(19) United States
(12) Patent Application Publication
(10) Pub. No.: US 2018/0061822 A1
(43) Pub. Date: Mar. 1, 2018

(54) SEMICONDUCTOR INTEGRATED CIRCUIT

(71) Applicant: KABUSHIKI KAISHA TOSHIBA, Tokyo (JP)

(72) Inventors: Yoshimasa KANDA, Kawasaki Kanagawa (JP); Sadao IMADA, Yokohama Kanagawa (JP)

(21) Appl. No.: 15/442,696

(22) Filed: Feb. 26, 2017

(30) Foreign Application Priority Data
Aug. 24, 2016 (JP) 2016-163748

(51) Int. Cl. H01L 27/02; H02H 9/04

(52) U.S. Cl. CPC H01L 27/0255; H02H 9/046; H01L 27/0288

(57) ABSTRACT

According to one embodiment, a semiconductor integrated circuit includes: a protection circuit including a first diode whose cathode is connected to a first wiring having a power-supply voltage and whose anode is connected to a first node, and a second diode whose anode is connected to a second wiring having a reference voltage and whose cathode is connected to the first node; a protection resistor that is connected to the first node at one end thereof and is connected to a second node at the other end thereof; a buffer circuit that is connected between the first wiring and the second wiring and has an input terminal to which a voltage at the second node is input; and a switching element that is connected between the first wiring and the second node.

### CROSS-REFERENCE TO RELATED APPLICATION

This application is based upon and claims the benefit of priority from Japanese Patent Application No. 2016-163748, filed Aug. 24, 2016, the entire contents of which are incorporated herein by reference.

### FIELD

Embodiments described herein relate generally to semiconductor integrated circuits.

### BACKGROUND

A semiconductor integrated circuit for on-vehicle use, for example, is required to be subjected to a high voltage stressing test (HVS test) in order to ensure that the device meets a desired quality standard. The HVS test is a test for detecting the presence of defective elements within a semiconductor integrated circuit by detecting fluctuations in electrical characteristics of the semiconductor integrated circuit when a voltage higher than a rated voltage is applied to the semiconductor integrated circuit.

In a logic input buffer circuit of the semiconductor integrated circuit, a CMOS inverter including a P-channel field-effect transistor (a PMOS transistor) and an N-channel field-effect transistor (an NMOS transistor) is used.

If the HVS test on the logic input buffer circuit of the semiconductor integrated circuit is conducted by use of an inspection device (a tester), a high voltage is applied to a logic input terminal. In general, since a probe pin allocated to the logic input terminal is typically used for a functional test, the probe pin is not suitable for the application of a high voltage for the HVS test.

Since there is a limit to the number of probe pins that can be used within a semiconductor integrated circuit, the allocation of one of these pins for HVS testing will limit the number of semiconductor integrated circuits which can be tested at one time, which is undesirable.

### DESCRIPTION OF THE DRAWINGS

FIG. 1 is a schematic diagram depicting a semiconductor integrated circuit according to a first embodiment;

FIG. 2 is a circuit diagram depicting a logic input buffer circuit according to the first embodiment;

FIG. 3 is a circuit diagram depicting a buffer circuit according to the first embodiment;

FIG. 4 is a circuit diagram depicting a control circuit according to the first embodiment;

FIG. 5 is a diagram of an HVS test according to the first embodiment;

FIG. 6 is a timing chart for explaining operations at the time of the HVS test according to the first embodiment;

FIG. 7 is a circuit diagram depicting a logic input buffer circuit according to a second embodiment; and

FIGS. 8A and 8B are diagrams for explaining the function of the logic input buffer circuit according to the second embodiment.

### DETAILED DESCRIPTION

Embodiments provide a semiconductor integrated circuit on which an HVS test can be easily conducted.

In general, according to one embodiment, a semiconductor integrated circuit includes: a protection circuit including a first diode whose cathode is connected to a first wiring having a power-supply voltage and whose anode is connected to a first node, and a second diode whose anode is connected to a second wiring having a reference voltage and whose cathode is connected to the first node; a protection resistor that is connected to the first node at one end thereof and is connected to a second node at the other end thereof; a buffer circuit that is connected between the first wiring and the second wiring and has an input terminal to which a voltage at the second node is input; and a switching element that is connected between the first wiring and the second node.

Hereinafter, embodiments will be described with reference to the drawings.

### First Embodiment

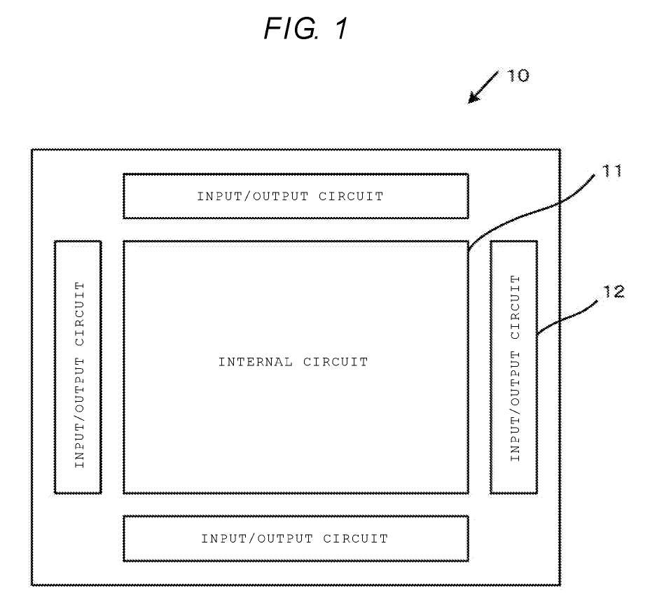

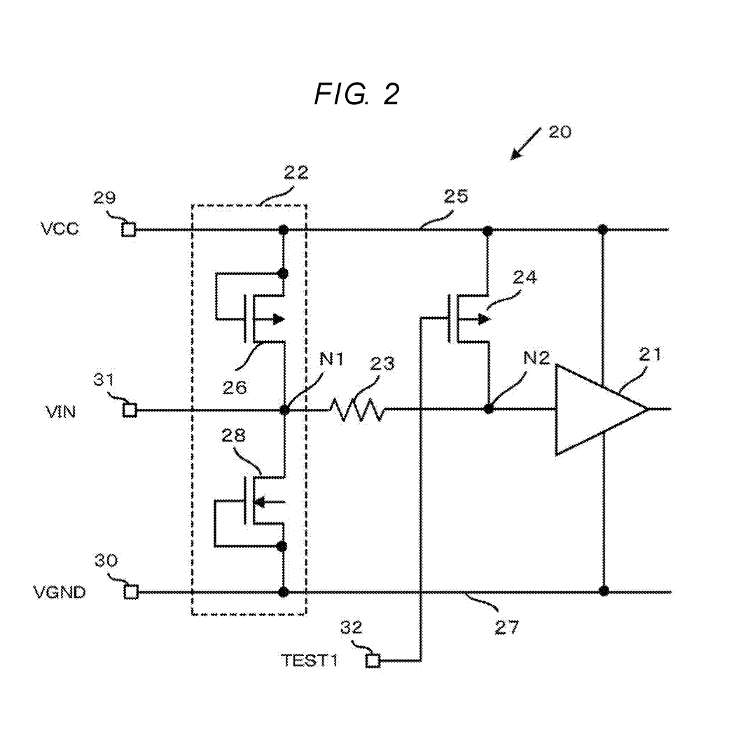

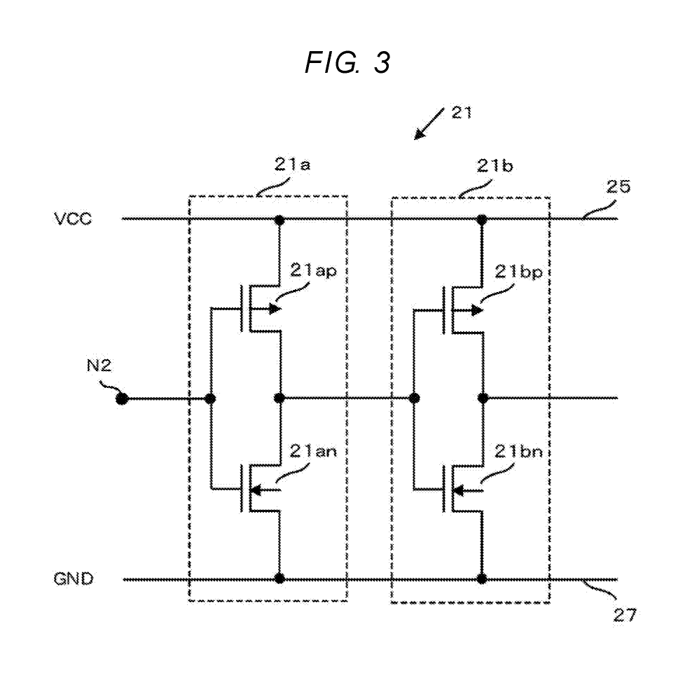

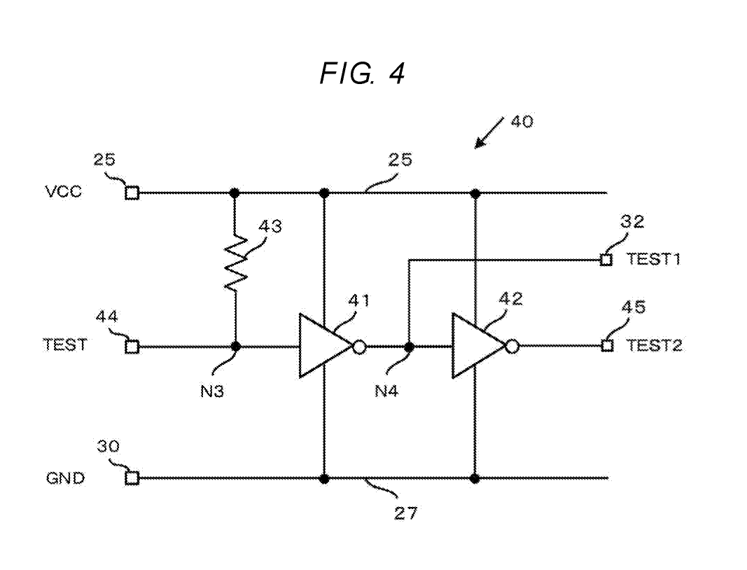

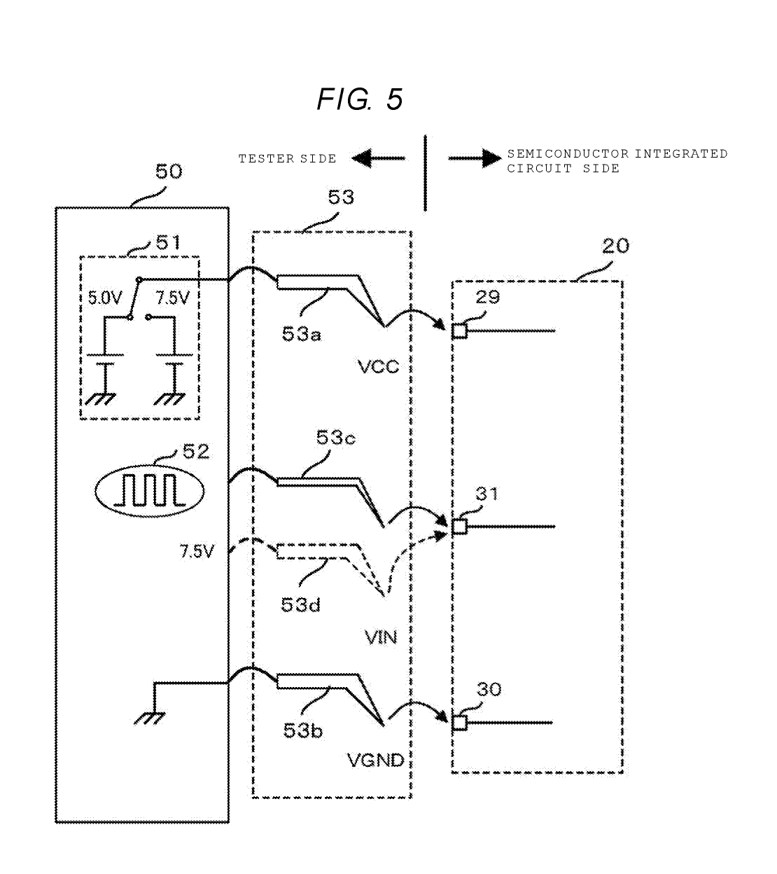

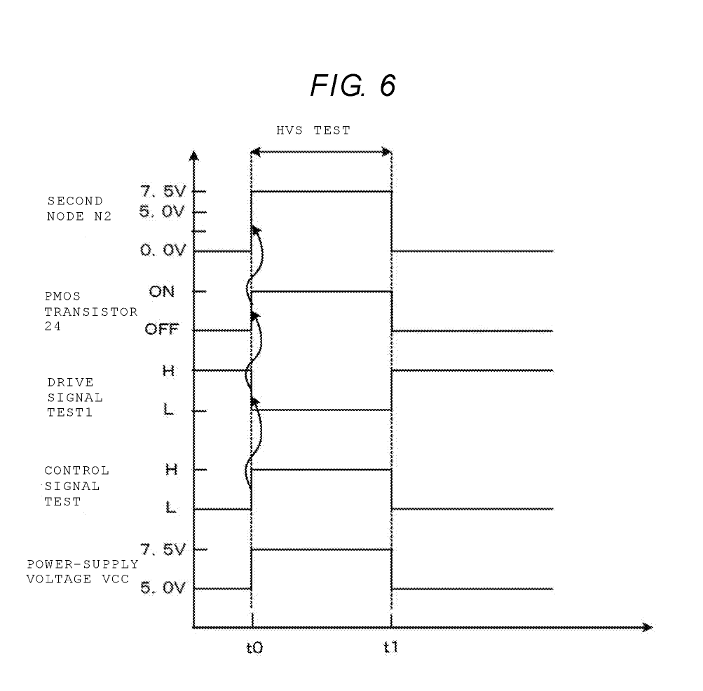

A semiconductor integrated circuit according to the present embodiment will be described by use of FIGS. 1 to 6. FIG. 1 is a layout diagram depicting the semiconductor integrated circuit of the present embodiment. FIG. 2 is a circuit diagram depicting a logic input buffer circuit. FIG. 3 is a circuit diagram depicting a buffer circuit. FIG. 4 is a circuit diagram depicting a control circuit. FIG. 5 is a diagram for explaining an HVS test. FIG. 6 is a timing chart for explaining operations at the time of the HVS test.

As depicted in FIG. 1, a semiconductor integrated circuit 10 of the present embodiment includes an internal circuit 11 including a logic circuit and an input/output circuit 12 including a logic input buffer circuit (hereinafter referred to simply as an input buffer circuit) and a logic output buffer circuit (hereinafter referred to simply as an output buffer circuit).

A logic signal is input to the internal circuit 11 via the input buffer circuit of the input/output circuit 12. The internal circuit 11 performs logic operation on the input logic signal. The operation result is output as a logic signal via the output buffer circuit of the input/output circuit 12. The internal circuit 11 may be arbitrarily configured, and the configuration thereof is not limited to a particular configuration.

As depicted in FIG. 2, an input buffer circuit 20 includes a buffer circuit 21, a protection circuit 22 and a protection resistor 23 for protecting the buffer circuit 21 from electrostatic discharge (ESD), and a switching element 24 for conducting a high voltage stressing (HVS) test on the input buffer circuit 20.

The buffer circuit 21 is connected between first wiring 25 and second wiring 27 and has an input terminal (not depicted in the drawing) to which a voltage at a second node N2 is input. As depicted in FIG. 3, the buffer circuit 21 has inverter circuits 21a and 21b connected in a cascade arrangement. The inverter circuit 21a is a CMOS inverter having a PMOS transistor 21ap and an NMOS transistor 21an. Likewise, the inverter circuit 21b is a CMOS inverter having a PMOS transistor 21bp and an NMOS transistor 21bn.

The protection circuit 22 includes a first diode 26 whose cathode is connected to the first wiring 25 having a power-supply voltage VCC and whose anode is connected to a first node N1 and a second diode 28 whose anode is connected to the second wiring 27 having a reference voltage VGND and whose cathode is connected to the first node N1. The first diode 26 is a PMOS transistor (hereinafter also referred to as the PMOS transistor 26) whose gate electrode and source electrode are connected to each other, for example. The second diode 28 is an NMOS transistor (hereinafter also referred to as the NMOS transistor 28) whose gate electrode and source electrode are connected to each other, for example. That is, each of the PMOS transistor 26 and the NMOS transistor 28 is so-called diode-connected.

The protection resistor 23 is connected to the first node N1 at one end thereof and is connected to the second node N2 at the other end thereof. The protection resistor 23 forms a CR low-pass filter along with a floating capacitance (not depicted in the drawing).

The switching element 24 is connected between the first wiring 25 and the second node N2. The switching element 24 is a PMOS transistor, for example. Hereinafter, the switching element 24 is also referred to as the PMOS transistor 24. The PMOS transistor 24 has a source electrode connected to the first wiring 25, a drain electrode connected to the second node N2, and a gate electrode connected to a control terminal 32.

The first wiring 25 is connected to a power-supply terminal 29. To the power-supply terminal 29, the power-supply voltage VCC is applied. The rating of the power-supply voltage VCC is 5±0.5 V, for example, and the power-supply voltage VCC is upped to 7.5 V, for example, at the time of the HVS test. The second wiring 27 is connected to a ground terminal 30. The reference voltage VGND of the ground terminal 30 is 0 V, for example.

An input terminal 31 is connected to the first node N1. To the input terminal 31, a logic signal having a level which is equal to the rated voltage of the power-supply voltage VCC is input. To the control terminal 32, a drive signal TEST1 (a first signal) for turning on/off the PMOS transistor 24 is input. When the drive signal TEST1 is High, for example, the drive signal is set to the power-supply voltage VCC, the PMOS transistor 24 is turned off. When the drive signal TEST1 is Low, for example, the drive signal is set to the reference voltage VGND, the PMOS transistor 24 is turned on.

The operations of the protection circuit 22 and the protection resistor 23 will be briefly described.

When a positive voltage which is larger than the sum (VCC+Vf26) of the power-supply voltage VCC and a forward voltage Vf26 of the first diode 26 is applied to the input terminal 31, a forward current flows through the first diode 26. When a negative voltage which is larger than the sum (VGND+Vf28) of the reference voltage VGND and a forward voltage Vf28 of the second diode 28 is applied to the input terminal 31, a forward current flows through the second diode 28.

That is, when noise mixes into the input terminal 31 and an input signal VIN is a positive pulse having a peak value which is greater than the sum (VCC+Vf26) of the power-supply voltage VCC and the forward voltage Vf26, since a forward current flows through the first diode 26, the peak value of the input signal VIN is clamped at the power-supply voltage VCC. Likewise, when the input signal VIN is a negative pulse having a peak value which is greater than the sum (VGND+Vf28) of the reference voltage VGND and the forward voltage Vf28, since a forward current flows through the second diode 28, the peak value of the input signal VIN is clamped at the reference voltage VGND.

The protection resistor 23 forms a low-pass filter along with a floating capacitance (not depicted in the drawing) and cuts an unnecessary high-frequency component from the input signal. The cutoff frequency fc of the low-pass filter is expressed as 1/ΩCR. Here, R represents the protection resistor and C represents the floating capacitance. With the protection circuit 22 and the protection resistor 23, the buffer circuit 21 is protected from ESD.

The operation of the switching element 24 will be described in detail.

As depicted in FIG. 4, a control circuit 40 for turning on/off the switching element 24 has inverter circuits 41 and 42 connected in a cascade arrangement. As is the case with the inverter circuits 21a and 21b depicted in FIG. 3, the inverter circuits 41 and 42 are CMOS inverters. Each of the inverter circuits 41 and 42 is connected between the first wiring 25 and the second wiring 27.

A resistor 43 is connected between the first wiring 25 and a third node N3. An input terminal 44 of a control signal and an input terminal of the inverter circuit 41 are connected to the third node N3. A voltage at the third node N3 is input to the inverter circuit 41. An output terminal of the inverter circuit 41 and an input terminal of the inverter circuit 42 are connected to a fourth node N4. The control terminal 32 depicted in FIG. 2 is connected to the fourth node N4. An output terminal of the inverter circuit 42 is connected to an output terminal 45. The output terminal 45 will be described later.

The inverter circuit 41 outputs the drive signal TEST1, which is obtained by inverting a control signal TEST, to the output terminal 32. The inverter circuit 42 outputs a drive signal TEST2, which is obtained by inverting the drive signal TEST1, to the output terminal 45.

The resistor 43 is provided to fix the output terminal 32 at Low and the output terminal 45 at High by pulling up the third node N3 to the power-supply voltage VCC when the input terminal 44 is in a floating state.

The HVS test which is conducted on the input buffer circuit 20 will be described by using FIGS. 5 and 6. Here, the description deals with a case where a large number of semiconductor integrated circuits 10 are formed on a semiconductor wafer and the HVS test is conducted on each semiconductor integrated circuit 10 at a wafer level by using a tester.

As depicted in FIG. 5, a tester 50 includes a power supply 51 that supplies a rated power-supply voltage VCC (for example, 5±0.5 V) for a function test (also referred to as an FC test) of the semiconductor integrated circuit 10 and a power-supply voltage VCC (for example, 7.5 V) for the HVS test, a signal generating circuit 52 that supplies a logic signal having a level which is equal to the rated power-supply voltage VCC for the function test, and so forth. The tester 50 is connected to the semiconductor integrated circuit 10 via a prober 53.

The prober 53 has a large number of pins for making contact with a large number of terminals (pads) provided in the semiconductor integrated circuit 10. Of a large number of pins, a pin 53a (also referred to as a power-supply pin) makes contact with the power-supply terminal 29, and a pin 53b (also referred to as a ground pin) makes contact with the ground terminal 30. A pin 53c (also referred to as an FC pin) makes contact with the input terminal 31.

At the time of the function test, a logic signal 52 having a level which is equal to the rated power-supply voltage VCC is supplied to the input terminal 31 via the pin 53c. In general, since the FC pin is finer than the power-supply pin and the ground pin, the maximum voltage which can be applied to a terminal with which contact is made via the FC pin is about 6 V.

In order to apply the power-supply voltage VCC for the HVS test to the input terminal 31 at the time of the HVS test, another pin 53d (also referred to as a DC pin) to which a voltage larger than 6 V can be applied is used. Since one DC pin is allocated to one logic input terminal, additional DC pins whose number is equal to the number of logic input terminals are necessary.

Since the number of semiconductor integrated circuits which can be tested at one time depends on the number of terminals of the semiconductor integrated circuit and the number of pins of the prober, the number of semiconductor integrated circuits which can be tested at one time is reduced with an increase in the number of pins allocated to one input terminal. As a result, it takes long time to complete the HVS test on the semiconductor integrated circuits at a wafer level, which may result in an increase in the cost of the HVS test.

The input buffer circuit 20 has the PMOS transistor 24, which is a switching element positioned between the first wiring 25 and the second node N2. By turning on the PMOS transistor 24 at the time of the HVS test, the power-supply voltage VCC for the HVS test can be applied directly to a gate terminal of the NMOS transistor 21an of the buffer circuit 21 without the use of the input terminal 31. That is, the DC pin for applying the power-supply voltage VCC for the HVS test to the input terminal 31 is not necessary.

As depicted in FIG. 6, at time t0, the power-supply voltage VCC is upped from 5.0 V for the FC test to 7.5 V for the HVS test and, at the same time, the control signal TEST changes from Low to High. The control circuit 40 changes the drive signal TEST1 from High to Low. As a result, the PMOS transistor 24 is turned on, and the power-supply voltage VCC upped to 7.5 V is applied to a gate electrode of the NMOS transistor 21an of the buffer circuit 21.

At time t1 after a lapse of a predetermined time, for example, 0.5 sec, the power-supply voltage VCC is dropped from 7.5 V to 5.0 V and, at the same time, the control signal TEST is changed from High to Low. The control circuit 40 changes the drive signal TEST1 from Low to High. As a result, the PMOS transistor 24 is turned off. Between time t0 and time t1, the HVS test is conducted.

In the input buffer circuit 20 of the present embodiment, by turning on the PMOS transistor 24, the power-supply voltage VCC for the HVS test can be applied to the gate electrode of the NMOS transistor 21an of the buffer circuit 21 without using the input terminal 31.

That is, the HVS test can be conducted on a large number of input buffer circuits 20 by turning on the respective PMOS transistor 24 of the input buffer circuits 20 by the drive signal TEST1.

As described above, in the semiconductor integrated circuit 10 of the present embodiment, since the input buffer circuit 20 has the PMOS transistor 24 which is a switching element, the power-supply voltage VCC for the HVS test can be applied to the gate electrode of the NMOS transistor 21an of the buffer circuit 21 without using the input terminal 31.

As a result, there is no need to reserve a large number of DC pins for the HVS test and the number of semiconductor integrated circuits which can be tested at one time is not reduced due to the need for the reserved DC pins. The time that elapses before the completion of the HVS test which is conducted on the semiconductor integrated circuits at a wafer level is reduced, and the cost of the HVS test is not increased.

Therefore, the semiconductor integrated circuit that allows the HVS test on the logic input buffer circuit to be easily conducted at a wafer level can be provided.

The above description deals with a case where the switching element 24 is the PMOS transistor 24, but the switching element 24 may be other switching elements. For example, a variable resistance element that reversibly changes from a high resistance to a low resistance when a voltage is applied thereto can also be used. Moreover, a pullup resistor may be connected between the switching element 24 and the second node N2.

The above description deals with a case where the first diode 26 is the PMOS transistor and the second diode 28 is the NMOS transistor, but the first and second diodes 26 and 28 may be normal diodes, for example, PN-junction diodes.

The above description deals with a case where the HVS test is conducted on a large number of semiconductor integrated circuits formed on a semiconductor wafer at a wafer level. However, the HVS test can be conducted in a similar manner on a plurality of semiconductor integrated circuits which are semiconductor integrated circuits on separate chips and arranged on a tape automated bonding (TAB) tape.

The above description deals with a case where the HVS test is conducted on an input buffer circuit, but the HVS test can be conducted on an output buffer circuit by providing the switching element 24 in the output buffer circuit. The output buffer circuit does not require the protection circuit 22 and the protection resistor 23 for protection against ESD.

### Second Embodiment

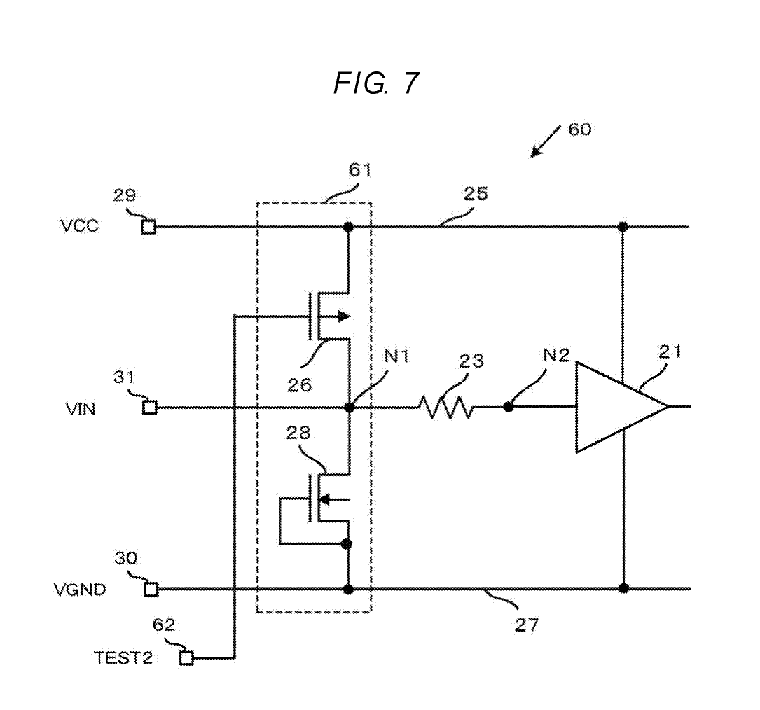

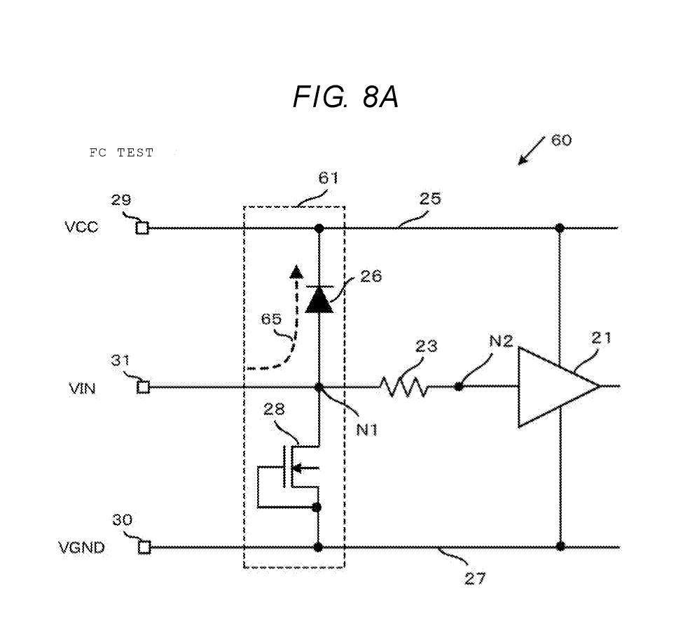

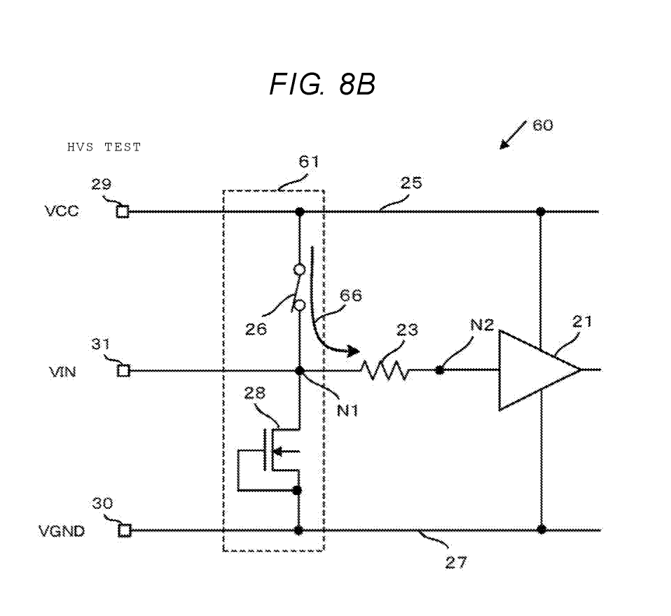

A semiconductor integrated circuit according to the present embodiment will be described by using FIG. 7 and FIGS. 8A and 8B. FIG. 7 is a circuit diagram depicting an input buffer circuit of the semiconductor integrated circuit of the present embodiment, and FIGS. 8A and 8B are diagrams for explaining the function of the input buffer circuit.

In the present embodiment, the same constituent portions as those of the above-described first embodiment are identified with the same characters and the explanations thereof are omitted, and only a difference from the first embodiment will be explained. The present embodiment differs from the first embodiment in that a PMOS transistor of a protection circuit is configured such that the PMOS transistor can be used as both a diode for protection against ESD and a switching element for the HVS test.

That is, as depicted in FIG. 7, an input buffer circuit 60 of the semiconductor integrated circuit of the present embodiment has a protection circuit 61. The protection circuit 61 is similar to the protection circuit 22 depicted in FIG. 2 in that the source electrode of the PMOS transistor 26 is connected to the first wiring 25 and the drain electrode thereof is connected to the first node N1, but differs from the protection circuit 22 in that the gate electrode of the PMOS transistor 26 is connected to a control terminal 62. The control terminal 62 is connected to the output terminal 45 of the control circuit 40 depicted in FIG. 4, and a drive signal TEST2 (a second signal) is input thereto.

The PMOS transistor 26 is turned off when the drive signal TEST2 is High (VCC) and is turned on when the drive signal TEST2 is Low (VGND). Therefore, at the time of the FC test, by turning off the PMOS transistor 26, the PMOS transistor 26 can be made to function as the first diode 26 depicted in FIG. 2. Moreover, at the time of the HVS test, by turning on the PMOS transistor 26, the PMOS transistor 26 can be made to function as the switching element 24 depicted in FIG. 2.

FIGS. 8A and 8B are diagrams for explaining the function of the protection circuit 61. FIG. 8A is a diagram depicting an equivalent circuit when the PMOS transistor 26 is off and FIG. 8B is a diagram depicting an equivalent circuit when the PMOS transistor 26 is on.

As depicted in FIG. 8A, since the gate electrode and the source electrode of the PMOS transistor 26 are connected in an equivalent manner when the drive signal TEST2 is High, the PMOS transistor 26 functions as the first diode 26 depicted in FIG. 2. When a positive pulse having a peak value which is greater than the sum of the power-supply voltage VCC and the forward voltage Vf26 of the first diode 26 mixes into the input terminal 31, a forward current flows through the first diode 26 as indicated by a dashed arrow 65.

As depicted in FIG. 8B, since the PMOS transistor 26 is turned on when the drive signal TEST2 is Low, the PMOS transistor 26 functions as the switching element 24 depicted in FIG. 2. As indicated by an arrow 66, the power-supply voltage VCC can be applied to the gate electrode of the NMOS transistor 21an in the buffer circuit 21. However, the input terminal 31 has to be kept in a floating state.

As described above, in the semiconductor integrated circuit of the present embodiment, the gate electrode of the PMOS transistor 26 of the protection circuit 61 is connected to the control terminal 62. The PMOS transistor 26 is turned on/off in response to the drive signal TEST2 which is applied to the control terminal 62.

As a result, at the time of the FC test, by turning off the PMOS transistor 26, the PMOS transistor 26 can be made to function as the first diode 26. At the time of the HVS test, by turning on the PMOS transistor 26, the PMOS transistor 26 can be made to function as the switching element 24.

Therefore, in this embodiment, the PMOS transistor 24 as the switching element is not necessary and the chip area of the semiconductor integrated circuit is not increased.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Incidentally, the configurations described below may also be possible.
(In some embodiments, a semiconductor integrated circuit may include a protection circuit including a first diode whose cathode is connected to first wiring having a power-supply voltage and whose anode is connected to a first node and a second diode whose anode is connected to second wiring having a reference voltage and whose cathode is connected to the first node, a protection resistor that is connected to the first node at one end thereof and is connected to a second node at the other end thereof, a buffer circuit that is connected between the first wiring and the second wiring and has an input terminal to which a voltage at the second node is input, and a switching element that is connected between the first wiring and the second node. In one configuration, the first diode is a P-channel field-effect transistor whose gate electrode and source electrode are connected to each other and the second diode is an N-channel field-effect transistor whose gate electrode and source electrode are connected to each other. The buffer circuit of the semiconductor integrated circuit may include CMOS inverters, each having a PMOS transistor and an NMOS transistor, the CMOS inverters being connected in a cascade arrangement.

What is claimed is:

1. A semiconductor integrated circuit comprising:
a protection circuit including a first diode whose cathode is connected to a first wiring having a power-supply voltage and whose anode is connected to a first node, and a second diode whose anode is connected to a second wiring having a reference voltage and whose cathode is connected to the first node;
a protection resistor that is connected to the first node at one end thereof and is connected to a second node at the other end thereof;
a buffer circuit that is connected between the first wiring and the second wiring and has an input terminal to which a voltage at the second node is input; and
a switching element that is connected between the first wiring and the second node.

2. The semiconductor integrated circuit according to claim 1, wherein
the switching element is a P-channel field-effect transistor whose source electrode is connected to the first wiring, whose drain electrode is connected to the second node, and whose gate electrode is connected to a control terminal.

3. The semiconductor integrated circuit according to claim 1, further comprising:
a control circuit that outputs a first signal to the control terminal, wherein the first signal is configured to turn on and off the switching element when a control signal is received by the control circuit.

4. The semiconductor integrated circuit according to claim 3, wherein
the control circuit has CMOS inverters connected in a cascaded arrangement, and
the control circuit outputs an inverted signal of the control signal as the first signal or a non-inverted signal of the control signal as the second signal.

5. The semiconductor integrated circuit according to claim 1, wherein the buffer circuit further comprises:
a first CMOS inverter circuit and a second CMOS inverter circuit that are connected in a cascaded arrangement, wherein the input terminal is connected to the gate electrodes of the first CMOS inverter circuit.

6. A semiconductor integrated circuit comprising:
a protection circuit including a P-channel field-effect transistor, whose source electrode is connected to a first wiring having a power-supply voltage, whose drain electrode is connected to a first node and whose gate electrode is connected to a control terminal, and a second diode whose anode is connected to a second wiring having a reference voltage and whose cathode is connected to the first node;
a protection resistor that is connected to the first node at one end thereof and is connected to a second node at the other end thereof; and
a buffer circuit that is connected between the first wiring and the second wiring and has an input terminal to which a voltage at the second node is input.

7. The semiconductor integrated circuit according to claim 6, wherein
in response to a signal which is input to the control terminal, the P-channel field-effect transistor functions as a first diode whose cathode is connected to the first wiring and whose anode is connected to the first node and a switching element for electrically connecting the first wiring and the first node.

8. The semiconductor integrated circuit according to claim 7, further comprising:
a control circuit that outputs a second signal for switching a function of the P-channel field-effect transistor in response to a control signal.

9. The semiconductor integrated circuit according to claim 8, wherein
the control circuit has CMOS inverters connected in a cascade arrangement, and
the control circuit outputs an inverted signal of the control signal as the first signal or a non-inverted signal of the control signal as the second signal.

10. The semiconductor integrated circuit according to claim 6, wherein the buffer circuit further comprises:
a first CMOS inverter circuit and a second CMOS inverter circuit that are connected in a cascaded arrangement, wherein the input terminal is connected to the gate electrodes of the first CMOS inverter circuit.

11. The semiconductor integrated circuit according to claim 6, wherein the buffer circuit further comprises an output that is connected to a logic circuit within the semiconductor integrated circuit.

12. A semiconductor integrated circuit comprising:
a power supply terminal connected to a first wiring that is configured to provide a first power-supply voltage;
a reference terminal connected to a second wiring that is configured to provide a reference voltage;
a protection circuit comprising:
a first diode whose cathode is connected to the first wiring and whose anode is connected to a third wiring at a first node, and
a second diode whose anode is connected to the second wiring and whose cathode is connected to the third wiring;
a switching element that is connected between the first wiring and a second node connected to the third wiring;
an input terminal connected to the third wiring, wherein the input terminal is configured to provide a second power-supply voltage, wherein the second power-supply voltage is less than the first power-supply voltage;
a protection resistor that has a first end and a second end, which is opposite to the first end, wherein the first end is connected to the first node and the input terminal, and the second end is connected to the second node; and
a buffer circuit that has an input that is connected to the second node and an output that is connected to a logic circuit within the semiconductor integrated circuit.

13. The semiconductor integrated circuit according to claim 12, wherein
the first diode further comprises a first P-channel field-effect transistor; and
the second diode further comprises a first N-channel field-effect transistor.

14. The semiconductor integrated circuit according to claim 12, wherein the switching element comprises a P-channel field-effect transistor whose cathode is connected to the first wiring and whose anode is connected to the second node.

15. The semiconductor integrated circuit according to claim 14, further comprising:
a testing terminal that is configured to receive a first signal from a control circuit and transmit the first signal to a gate of the P-channel field-effect transistor.

16. The semiconductor integrated circuit according to claim 14, wherein
the control circuit has CMOS inverters connected in a cascaded arrangement, and
the control circuit outputs an inverted signal of the control signal as the first signal or a non-inverted signal of the control signal as the second signal.

17. The semiconductor integrated circuit according to claim 12, wherein the buffer circuit further comprises:
a first CMOS inverter circuit and a second CMOS inverter circuit that are connected in a cascaded arrangement, wherein the buffer input is connected to the gate electrodes of the first CMOS inverter circuit.

18. The semiconductor integrated circuit according to claim 12, wherein the switching element is coupled to a testing terminal that is configured to provide a control signal that causes the switching element to perform a switching function, and wherein a probing device is configured to test the semiconductor integrated circuit using a plurality of pins, wherein the plurality of pins comprise:
one or more first pins that are configured to contact the power-supply terminal;
one or more second pins that are configured to contact the reference terminal;
one or more third pins that are configured to contact the input terminal; and
one or more fourth pins that are configured to contact the testing terminal,
wherein the one or more third pins are finer than the one or more first pins and the one or more second pins, and the one or more third pins are the only pins that are configured to contact the input terminal.

19. The semiconductor integrated circuit according to claim 18, wherein the one or more third pins are also finer than the one or more fourth pins.
